(19) United States
(12) Patent Application Publication
(10) Pub. No.: US 2026/0037173 A1
(43) Pub. Date: Feb. 5, 2026

(54) SYSTEMS AND METHODS FOR WEIGHT REMAPPING CIRCUIT

(71) Applicant: Taiwan Semiconductor Manufacturing Company, Ltd., Hsinchu (TW)

(72) Inventors: Hidehiro Fujiwara, Hsinchu City (TW); Haruki Mori, Hsinchu City (TW); Je-Min Hung, Hsinchu City (TW); Chia-Fu Lee, Hsinchu City (TW); Yu-Der Chih, Hsinchu City (TW); Jonathan Tsung-Yung Chang, Hsinchu City (TW)

(73) Assignee: Taiwan Semiconductor Manufacturing Company, Ltd., Hsinchu (TW)

(21) Appl. No.: 18/790,526

(22) Filed: Jul. 31, 2024

(51) Int. Cl. G06F 3/06; G11C 7/10; G11C 11/412; H03K 19/20

(52) U.S. Cl. CPC G06F 3/0655; G06F 3/0604; G06F 3/0679; G11C 7/1051; G11C 7/1078; H03K 19/20; G11C 11/412

(57) ABSTRACT

A circuit for weight mapping for a computation in memory circuit includes memory cells, first address lines, each coupled with a corresponding one of the memory cells, and second address lines, each coupled with a set of cells in the memory cells. One or more cells in the memory cells are configured to be accessed for one or more weight values, when one or more of the first address lines and one or more of the second address lines corresponding to the one or more cells in the memory cells are asserted. The one or more cells that are accessed at a first time correspond to a first weight matrix, and the one or more cells that are accessed at a second time correspond to a second weight matrix, the second weight matrix being a transposed one of the first weight matrix.

### BACKGROUND

Computer artificial intelligence (AI) has been built on machine learning, for example, using deep learning techniques. With machine learning, a computing system organized as a neural network computes a statistical likelihood of a match of input data with prior computed data. A neural network refers to a number of interconnected processing nodes that enable the analysis of data to compare an input to “trained” data. Trained data refers to computational analysis of properties of known data to develop models to use to compare input data. An example of an application of AI and data training is found in object recognition, where a system analyzes the properties of many (e.g., thousands or more) of images to determine patterns that can be used to perform statistical analysis to identify an input object.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 and FIG. 2 illustrate schematic diagrams of example circuits, in accordance with some embodiments of the present disclosure.

FIG. 3 illustrates a schematic diagram of an example weight mapping process, in accordance with some embodiments of the present disclosure.

FIG. 4 to FIG. 7 illustrate schematic diagrams of example circuits, in accordance with some embodiments of the present disclosure.

FIG. 8 to FIG. 10 illustrate schematic diagrams of example weight mapping processes, in accordance with some embodiments of the present disclosure.

FIG. 11 illustrates a flow chart of an example method of operating a circuit, in accordance with various embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Neural networks compute “weights” to perform computation on new data (an input data “word”). Neural networks use multiple layers of computational nodes, where deeper layers perform computations based on results of computations performed by higher layers. Machine learning currently relies on the computation of dot-products and absolute difference of vectors, typically computed with multiply-accumulate (MAC) operations performed on the parameters, input data and weights. The computation of large and deep neural networks typically involves so many data elements, and thus it is not practical to store them in processor cache. Accordingly, these data elements are usually stored in a memory.

In general, machine learning is computationally intensive with the computation and comparison of many different data elements. The computation of operations within a processor is orders of magnitude faster than the transfer of data elements between the processor and main memory resources. Placing all the data elements closer to the processor in caches is prohibitively expensive for the great majority of practical systems due to the memory sizes needed to store the data elements. Thus, the transfer of data elements becomes a major bottleneck for AI computations. As the data sets increase, the time and power/energy a computing system uses for moving data elements around can end up being multiples of the time and power used to actually perform computations.

In this regard, computing-in-memory (CIM) circuits have been proposed to perform such MAC operations. A CIM circuit conducts data processing in situ within a suitable memory circuit. The CIM circuit suppresses the latency for data/program fetch and output results upload in corresponding memory (e.g. a memory array), thus solving the memory (or von Neumann) bottleneck of conventional computers. Another key advantage of the CIM circuit is the high computing parallelism, thanks to the specific architecture of the memory array, where computation can take place along several current paths at the same time. The CIM circuit also benefits from the high density of multiple memory arrays with computational devices, which generally feature excellent scalability and the capability of 3D integration. As a non-limiting example, the CIM circuit targeted for various machine learning applications can perform the MAC operations locally within the memory (i.e., without having to send data elements to a host processor) to enable higher throughput dot-product of neuron activation and weight matrices, while still providing higher performance and lower energy compared to computation by the host processor.

In machine learning applications, the CIM circuit is frequently configured to process dot product multiplications based on performing MAC operations on a large number of data elements (e.g., an input word vector and a weight matrix) with rearranged weight feature maps, which may require additional cycles and/or buffers and thus rearrangement of the weight matrix. Such an approach thereby may cause additional costs.

The present disclosure provides various embodiments of a CIM circuit that can perform MAC operations with rearranged weight feature maps without performing additional cycles and/or buffers. According to the present disclosure, the CIM circuit can provide an enable signal and an address signal and access a memory array based on the enable signal and the address signal. The CIM circuit can provide a first address signal at a first time to access the memory array based on a first weight matrix, and can provide a second address signal at a second time to access the memory array based on a second weight matrix, the second weight matrix being a transposed one of the first weight matrix. By accessing the memory array based on the weight matrix and the transposed matrix of the weight matrix in flexible manners, the CIM circuit disclosed herein can perform MAC operations with rearranged weight feature maps without performing additional cycles and/or buffers (e.g., within a single macro).

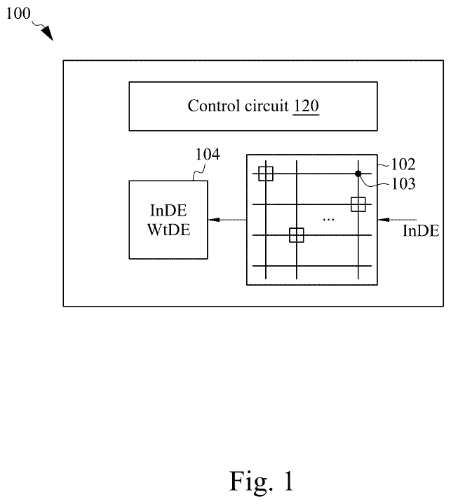

FIG. 1 illustrate schematic diagrams of example circuits, in accordance with some embodiments of the present disclosure. More specifically, shown in FIG. 1 is an example data computation circuit 100, in accordance with some embodiments of the present disclosure. In the illustrated embodiment depicted in FIG. 1, the data computation circuit 100, also referred to as (e.g., CIM) circuit 100 or memory circuit 100, includes various components collectively configured to perform in-memory computations (e.g., multiply-accumulate (MAC) operations) on an input word vector and a weight matrix. The input word vector can include a plural number of input data elements InDE, and the weight matrix can include a plural number of weight data elements WtDE.

As shown, the circuit 100 includes a memory circuit 102, an input circuit 104, and a control circuit 120. It should be appreciated that the block diagram of the circuit depicted in FIG. 1 is simplified, and thus, the circuit 100 can include any of various other components while remaining within the scope of the present disclosure.

The memory circuit 102 may include one or more memory arrays and one or more corresponding circuits. The memory arrays are each a storage device including a number of storage elements (sometimes referred to as “memory array,” “memory cells,” etc.) 103, each of the storage elements 103 including an electrical, electromechanical, electromagnetic, or other device configured to store one or more data elements, each data element including one or more data bits represented by logical states. In some embodiments, a logical state corresponds to a voltage level of an electrical charge stored in a portion or all of a storage element 103. In some embodiments, a logical state corresponds to a physical property, e.g., a resistance or magnetic orientation, of a portion or all of a storage element 103.

In some embodiments, the storage element 103 includes one or more static random-access memory (SRAM) cells. In various embodiments, an SRAM cell includes a number of transistors, e.g., a five-transistor (5T) SRAM cell, a six-transistor (6T) SRAM cell, an eight-transistor (8T) SRAM cell, a nine-transistor (9T) SRAM cell, etc. In some embodiments, an SRAM cell includes a multi-track SRAM cell. In some embodiments, an SRAM cell includes a length at least two times greater than a width.

In some embodiments, the storage element 103 includes one or more dynamic random-access memory (DRAM) cells, resistive random-access memory (RRAM) cells, magnetoresistive random-access memory (MRAM) cells, ferroelectric random-access memory (FeRAM) cells, NOR flash cells, NAND flash cells, conductive-bridging random-access memory (CBRAM) cells, data registers, non-volatile memory (NVM) cells, 3D NVM cells, or other memory cell types capable of storing bit data.

In addition to the memory array(s), the memory circuit 102 can include a number of circuits to access or otherwise control the memory arrays. For example, the memory circuit 102 may include a number of (e.g., word line) drivers operatively coupled to the memory arrays. The drivers can apply signals (e.g., voltages) to the corresponding storage elements 103 to allow those storage elements 103 to be accessed (e.g., programmed, read, etc.). For another example, the memory circuit 102 may include a number of programming circuits and/or read circuits that are operatively coupled to the memory arrays.

The memory arrays of the memory circuit 102 are each configured to store a number of the weight data elements WtDE. In some embodiments, the programming circuits may write the weight data elements WtDE into corresponding storage elements 103 of the memory arrays, respectively, while the reading circuit may read bits written into the storage elements 103, so as to verify or otherwise test whether the written weight data elements WtDE are correct. The drivers of the memory circuit 102 can include or be operatively coupled to a number of input activation latches that are configured to receive and temporarily store the input data elements InDE. In some other embodiments, such input activation latches may be part of the input circuit 104, which can further include a number of buffers that are configured to temporarily store the weight data elements WtDE retrieved from the memory arrays of the memory circuit 102. As such, the input circuit 104 can receive the input data elements InDE and the weight data elements WtDE.

In various embodiments of the present disclosure, based on the input word vector (including, e.g., the input data elements InDE) and the weight matrix (including, e.g., the weight data elements WtDE), the circuit 100 (e.g., the control circuit 120) can be configured to perform MAC operations.

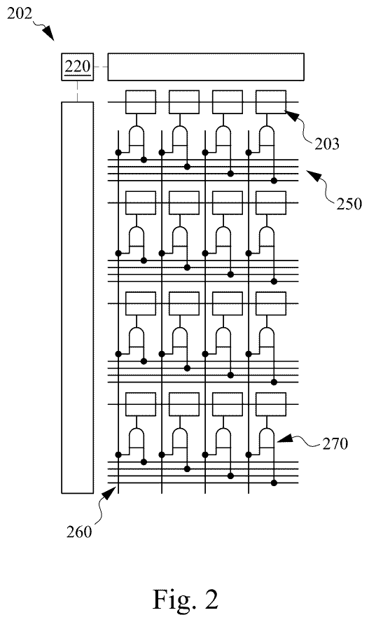

FIG. 2 illustrates a schematic diagram of an example memory circuit 202, in accordance with some embodiments of the present disclosure. More specifically, the memory circuit 202 is an example of the memory circuit 102. The memory circuit 202 may be substantially similar to and/or incorporate features of the memory circuit 102. The memory circuit 202 can include a plurality of memory cells (sometimes referred to as “memory array”) 203, which may be substantially similar to and/or incorporate features of the storage elements 103. Shown in FIG. 2 is a non-limiting example of the memory circuit 202. In some embodiments, the memory circuit 202 can include more, fewer, or different components than shown in or described with respect to FIG. 2.

The memory circuit 202 can include a plurality of first address lines 250. Each of the plurality of first address lines 250 can be coupled with a corresponding one of the plurality of memory cells 203. In some embodiments, a number of address lines in the plurality of first address lines 250 can correspond to a number of memory cells in the plurality of memory cells 230. Each of the plurality of first address lines 250 can be configured to receive an address signal indicating the corresponding one of the plurality of memory cells 203. In some embodiments, each of the plurality of first address lines 250 can be configured to be asserted with the address signal to access the corresponding one of the plurality of memory cells 203.

The memory circuit 202 can include a plurality of second address lines 260. Each of the plurality of second address lines 260 can be coupled with a corresponding set of memory cells in the plurality of memory cells 230 (e.g., the memory cells in a column of the plurality of memory cells 230). In some embodiments, a number of address lines in the plurality of second address lines 260 can correspond to a number of rows or columns in the plurality of memory cells 203. Each of the plurality of second address lines 260 can be configured to receive an enable (e.g., write enable, read enable, etc.) signal corresponding to the corresponding set of memory cells in the plurality of memory cells 230. In some embodiments, each of the plurality of second address lines 260 can be configured to be asserted with the enable signal to access the corresponding set of memory cells in the plurality of memory cells 203.

The memory circuit 202 can include a control circuit 220 operably coupled with the plurality of memory cells 203. In some embodiments, the control circuit 220 may be substantially similar to and/or incorporate features of the control circuit 120. In some embodiments, the control circuit 220 may include or be included in the control circuit 120. In some embodiments, the control circuit 220 may be operably coupled with the control circuit 120.

In some embodiments, the control circuit 220 can be configured to provide the enable signal and the address signal. For example, the control circuit 220 can provide the enable signal through the second address lines 260 to the plurality of memory cells 203. The control circuit 220 can provide the address signal through the first address lines 250 to the plurality of memory cells 203. In some embodiments, the control circuit 220 can access, based on the enable signal and the address signal, at least one memory cell of the plurality of memory cells 203.

In some embodiments, the control circuit 220 can be configured to provide a first address signal at a first time to access the plurality of memory cells 203 based on a first weight matrix, and configured to provide a second address signal at a second time to access the plurality of memory cells 203 based on a second weight matrix. In some embodiments, the second weight matrix may be a transposed one of the first weight matrix.

In some embodiments, one or more memory cells in the plurality of memory cells 203 can be configured to be accessed (e.g., written, read, etc.) for one or more weight values, when one or more of the plurality of first address lines 250 and one or more of the plurality of second address lines 260 corresponding to the one or more cells in the plurality of memory cells 203 are asserted. In some embodiments, the one or more cells that are accessed at a first time can correspond to a first weight matrix, and the one or more cells that are accessed at a second time can correspond to a second weight matrix. In some embodiments, the second weight matrix can be a transposed one of the first weight matrix.

In some embodiments, the memory circuit 202 can include a plurality of logic gates 270. For example, the plurality of logic gates 270 may be a plurality of logic AND gates. The plurality of logic gates 270 can be operably coupled between a corresponding one of the plurality of first address lines 250 and a corresponding one of the plurality of second address lines 260. In some embodiments, each of the plurality of logic gates 270 (e.g., a logic AND gate) can include a first input to receive the enable signal (e.g., through the corresponding one of the plurality of first address lines 250) and a second input to receive the address signal (e.g., through the corresponding one of the plurality of second address lines 260). In some embodiments, each of the plurality of logic gates 270 can include an output operably coupled with the corresponding one of the plurality of memory cells 203. The plurality of logic gates 270 can provide a logic operation (e.g., a logic AND operation) through the output.

In some embodiments, the memory circuit 202 can include a multiplexer operably coupled between the plurality of memory cells 203 and the control circuit 220. In some embodiments, the plurality of first address lines 250, the plurality of second address lines 260, and the plurality of logic gates 270 can define the multiplexer. In some embodiments, the multiplexer can be or include any logic component and/or control circuit configured to access the plurality of memory cells 203 based on a first weight matrix and a second weight matrix that is a transposed matrix of the first weight matrix.

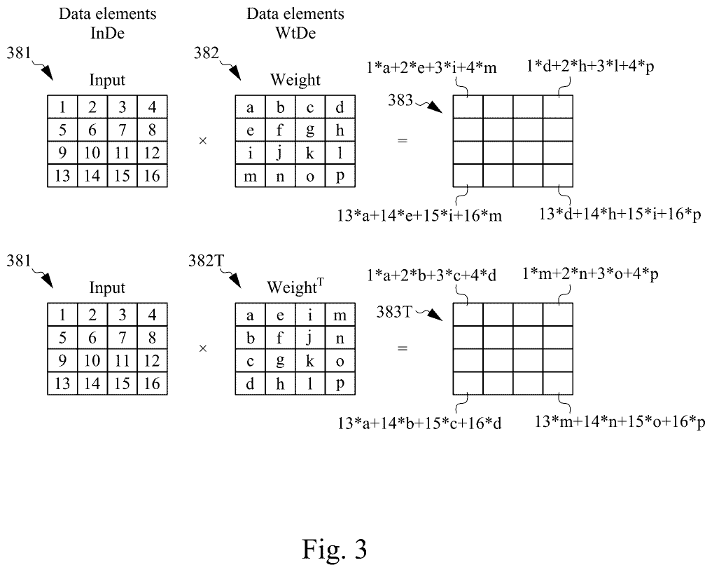

FIG. 3 illustrates a schematic diagram of an example weight mapping process, in accordance with some embodiments of the present disclosure. The weight mapping process shown in FIG. 3 may be associated with the memory circuit 102, the memory circuit 202, etc. Shown in FIG. 3 is a non-limiting example of the weight mapping process.

In some embodiments, a matrix 381 may correspond to input data elements InDe (e.g., of FIG. 1). In some embodiments, a matrix 382 may correspond to weight data elements WtDe (e.g., of FIG. 1), and a matrix 382T may correspond to a transposed matrix of the matrix 382. A matrix 383 may correspond to a matrix resulting from a first MAC operation of the matrix 381 and the matrix 382. A matrix 383T may correspond to a matrix resulting from a second MAC operation of the matrix 381 and the matrix 382T. A memory circuit as disclosed herein (e.g., the memory circuit 202) can be configured to perform the first MAC operation (e.g., based on a non-transposed weight matrix) and the second MAC operation (e.g., based on a transposed weight matrix) without performing additional cycles and/or buffers (e.g., within a single macro).

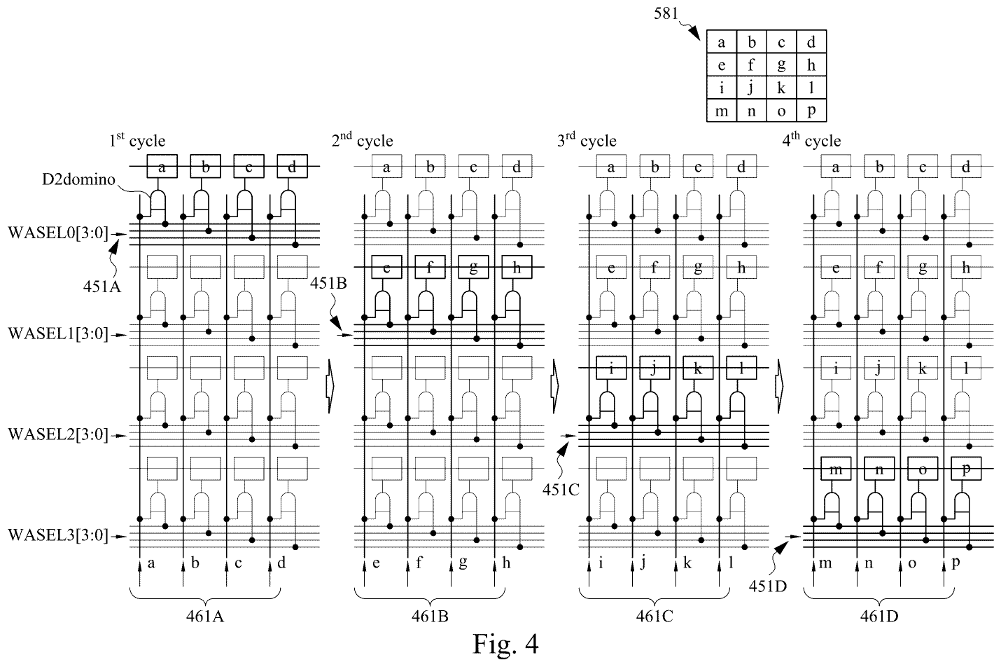

FIG. 4 illustrates a schematic diagram of an example memory circuit, in accordance with some embodiments of the present disclosure. More specifically, shown in FIG. 4 is the memory circuit 202 (the control circuit 220 not shown) at a first time, during an example write operation associated with a weight matrix 581. The write operation shown in FIG. 4 is a non-limiting example. In some embodiments, the memory circuit 202 can be operated with more, fewer, or different operations than shown in or described with respect to FIG. 4.

In some embodiments, the control circuit 220 can be configured to provide an enable signal 461A and an address signal 451A (e.g., WASEL0[3:0]) during a first cycle of the first time. During the first cycle, the control circuit 220 can be configured to access (e.g., write) based on the enable signal 461A and the address signal 451A, at least one memory cell of the plurality of memory cells 203. For example, as shown, a first subset of address lines corresponding to a first row of the plurality of memory cells 203 can be asserted to provide the address signal 451A, while the enable signal 461A (e.g., “a,” “b,” “c,” and “d”) is asserted. This can write on the memory cells in the first row of the plurality of memory cells 203. For example, in the first subset of address lines, the address signal 451A includes a first address line signal, which is coupled to a first memory cell through a corresponding one of the plurality of logic gates 270. The enable signal 461A includes a first enable line signal (e.g., “a,” for the first column), which is coupled to a first memory cell through the corresponding one of the plurality of logic gates 270. Based on a logic operation of the first address line signal and the first enable line signal, the first memory cell can be written for a logic value (e.g., “a”). Likewise, the other memory cells in the first row can be written for logic values (e.g., “b,” “c,” and “d”).

In some embodiments, the control circuit 220 can be configured to provide an enable signal 461B and an address signal 451B (e.g., WASEL1[3:0]) during a second cycle of the first time. During the second cycle, the control circuit 220 can be configured to access (e.g., write) based on the enable signal 461B and the address signal 451B, at least one memory cell of the plurality of memory cells 203. For example, as shown, a second subset of address lines corresponding to a second row of the plurality of memory cells 203 can be asserted to provide the address signal 451B, while the enable signal 461B (e.g., “e,” “f,” “g,” and “h”) is asserted. This can write on the memory cells in the second row of the plurality of memory cells 203. For example, in the second subset of address lines, the address signal 451B includes a second address line signal, which is coupled to a second memory cell through a corresponding one of the plurality of logic gates 270. The enable signal 461B includes a second enable line signal (e.g., “e,” for the first column), which is coupled to a second memory cell through the corresponding one of the plurality of logic gates 270. Based on a logic operation of the second address line signal and the second enable line signal, the second memory cell can be written for a logic value (e.g., “e”). Likewise, the other memory cells in the second row can be written for logic values (e.g., “f,” “g,” and “h”).

In some embodiments, the control circuit 220 can be configured to provide an enable signal 461C and an address signal 451C (e.g., WASEL2[3:0]) during a third cycle of the first time. During the third cycle, the control circuit 220 can be configured to access (e.g., write) based on the enable signal 461C and the address signal 451C, at least one memory cell of the plurality of memory cells 203. For example, as shown, a third subset of address lines corresponding to a third row of the plurality of memory cells 203 can be asserted to provide the address signal 451C, while the enable signal 461C (e.g., “i,” “j,” “k,” and “l”) is asserted. This can write on the memory cells in the third row of the plurality of memory cells 203. For example, in the third subset of address lines, the address signal 451C includes a third address line signal, which is coupled to a third memory cell through a corresponding one of the plurality of logic gates 270. The enable signal 461C includes a third enable line signal (e.g., “i,” for the first column), which is coupled to a third memory cell through the corresponding one of the plurality of logic gates 270. Based on a logic operation of the third address line signal and the third enable line signal, the third memory cell can be written for a logic value (e.g., “i”). Likewise, the other memory cells in the third row can be written for logic values (e.g., “j,” “k,” and “l”).

In some embodiments, the control circuit 220 can be configured to provide an enable signal 461D and an address signal 451D (e.g., WASEL3[3:0]) during a fourth cycle of the first time. During the fourth cycle, the control circuit 220 can be configured to access (e.g., write) based on the enable signal 461D and the address signal 451D, at least one memory cell of the plurality of memory cells 203. For example, as shown, a fourth subset of address lines corresponding to a fourth row of the plurality of memory cells 203 can be asserted to provide the address signal 451D, while the enable signal 461D (e.g., “m,” “n,” “o,” and “p”) is asserted. This can write on the memory cells in the fourth row of the plurality of memory cells 203. As such, in some embodiments, the control circuit 220 can access the plurality of memory cells 203 to write the weight matrix 581. For example, in the fourth subset of address lines, the address signal 451D includes a fourth address line signal, which is coupled to a fourth memory cell through a corresponding one of the plurality of logic gates 270. The enable signal 461D includes a fourth enable line signal (e.g., “m,” for the first column), which is coupled to a fourth memory cell through the corresponding one of the plurality of logic gates 270. Based on a logic operation of the fourth address line signal and the fourth enable line signal, the fourth memory cell can be written for a logic value (e.g., “m”). Likewise, the other memory cells in the fourth row can be written for logic values (e.g., “n,” “o,” and “p”).

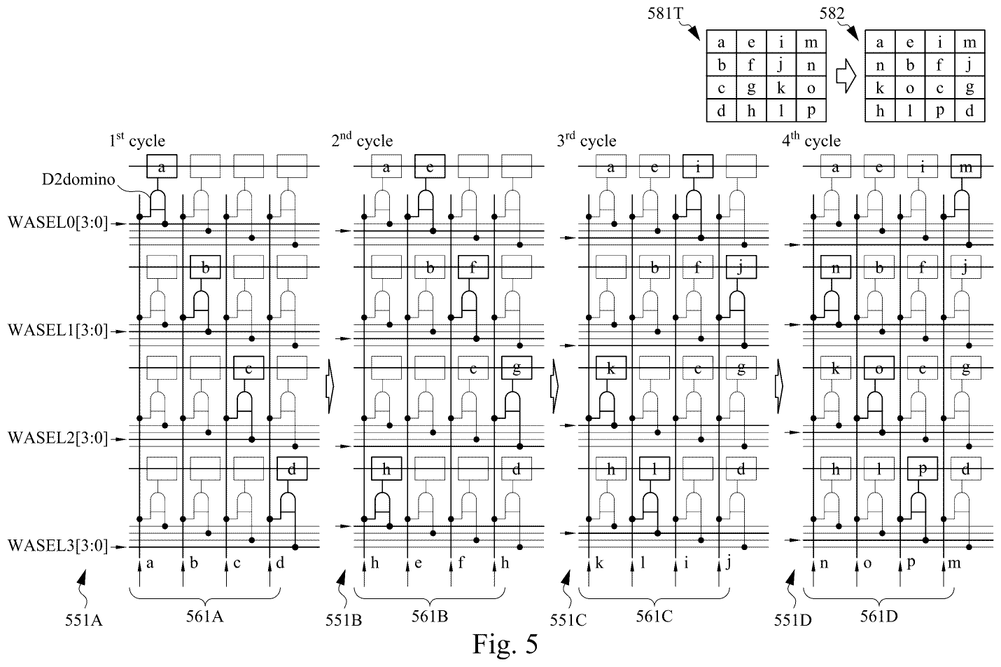

FIG. 5 illustrates a schematic diagram of an example memory circuit, in accordance with some embodiments of the present disclosure. More specifically, shown in FIG. 5 is the memory circuit 202 (the control circuit 220 not shown) at a second time, during an example write operation associated with a weight matrix 581T. The write operation shown in FIG. 5 is a non-limiting example. In some embodiments, the memory circuit 202 can be operated with more, fewer, or different operations than shown in or described with respect to FIG. 5. In some embodiments, the memory circuit 202 can be configured to access the plurality of memory cells 203 based on a shifted matrix 582, in which one or more rows in the weight matrix 581T are shifted.

In some embodiments, the control circuit 220 can be configured to provide an address signal. The address signal includes a first address signal 551A during a first cycle, a second address signal 551B during a second cycle, a third address signal 551C during a third cycle, and a fourth address signal 551D during a fourth cycle. The first address signal 551A includes a first address line signal (e.g., asserted through a first row in the first subset of the plurality of first address lines 250). The first address signal 551A includes a second address line signal (e.g., asserted through a second row in the second subset of the plurality of first address lines 250). The first address signal 551A includes a third address line signal (e.g., asserted through a third row in the third subset of the plurality of first address lines 250). The first address signal 551A includes a fourth address line signal (e.g., asserted through a fourth row in the fourth subset of the plurality of first address lines 250). Likewise, for each cycle, each address signal can include address line signals different for different subsets of the plurality of first address lines 250.

In some embodiments, the control circuit 220 can be configured to provide an enable signal 561A and the address signal 551A during a first cycle of the second time. During the first cycle, the control circuit 220 can be configured to access (e.g., write) based on the enable signal 561A and the address signal 551A, at least one memory cell of the plurality of memory cells 203. For example, as shown, address line signals different for different subsets of the plurality of first address lines 250 can be asserted, while the enable signal 561A (e.g., “a,” “b,” “c,” and “d”) is asserted. This can write on the memory cells that are accessed by the enable signal 561A and the address signal 551A. For example, a first column memory cell in the first row of the plurality of memory cells 203 can be written for a logic value (e.g., “a”), a second column memory cell in the second row of the plurality of memory cells 203 can be written for a logic value (e.g., “b”), a third column memory cell in the third row of the plurality of memory cells 203 can be written for a logic value (e.g., “c”), and a fourth column memory cell in the fourth row of the plurality of memory cells 203 can be written for a logic value (e.g., “d”).

In some embodiments, the control circuit 220 can be configured to provide an enable signal 561B and the address signal 551B during a second cycle of the second time. During the second cycle, the control circuit 220 can be configured to access (e.g., write) based on the enable signal 561B and the address signal 551B, at least one memory cell of the plurality of memory cells 203. For example, as shown, address line signals different for different subsets of the plurality of first address lines 250 can be asserted, while the enable signal 561B (e.g., “h,” “e,” “f,” and “g”) is asserted. This can write on the memory cells that are accessed by the enable signal 561B and the address signal 551B. For example, a second column memory cell in the first row of the plurality of memory cells 203 can be written for a logic value (e.g., “e”), a third column memory cell in the second row of the plurality of memory cells 203 can be written for a logic value (e.g., “e”), a fourth column memory cell in the third row of the plurality of memory cells 203 can be written for a logic value (e.g., “g”), and a first column memory cell in the fourth row of the plurality of memory cells 203 can be written for a logic value (e.g., “h”).

In some embodiments, the control circuit 220 can be configured to provide an enable signal 561C and the address signal 551C during a third cycle of the second time. During the third cycle, the control circuit 220 can be configured to access (e.g., write) based on the enable signal 561C and the address signal 551C, at least one memory cell of the plurality of memory cells 203. For example, as shown, address line signals different for different subsets of the plurality of first address lines 250 can be asserted, while the enable signal 561C (e.g., “k,” “l,” “i,” and “j”) is asserted. This can write on the memory cells that are accessed by the enable signal 561C and the address signal 551C. For example, a third column memory cell in the first row of the plurality of memory cells 203 can be written for a logic value (e.g., “i”), a fourth column memory cell in the second row of the plurality of memory cells 203 can be written for a logic value (e.g., “j”), a first column memory cell in the third row of the plurality of memory cells 203 can be written for a logic value (e.g., “k”), and a second column memory cell in the fourth row of the plurality of memory cells 203 can be written for a logic value (e.g., “l”).

In some embodiments, the control circuit 220 can be configured to provide an enable signal 561D and the address signal 551D during a fourth cycle of the second time. During the third cycle, the control circuit 220 can be configured to access (e.g., write) based on the enable signal 561D and the address signal 551D, at least one memory cell of the plurality of memory cells 203. For example, as shown, address line signals different for different subsets of the plurality of first address lines 250 can be asserted, while the enable signal 561D (e.g., “n,” “o,” “p,” and “m”) is asserted. This can write on the memory cells that are accessed by the enable signal 561D and the address signal 551D. For example, a fourth column memory cell in the first row of the plurality of memory cells 203 can be written for a logic value (e.g., “m”), a first column memory cell in the second row of the plurality of memory cells 203 can be written for a logic value (e.g., “n”), a second column memory cell in the third row of the plurality of memory cells 203 can be written for a logic value (e.g., “o”), and a third column memory cell in the fourth row of the plurality of memory cells 203 can be written for a logic value (e.g., “p”).

As discussed with respect to and shown in FIG. 4 and FIG. 5, the control circuit 220 can assert different address lines in various manners. In some embodiments, the control circuit 220 can be configured to alternately assert different rows in the plurality of memory cells 203. In some embodiments, when the control circuit 220 asserts one row in the plurality of memory cells 203, the control circuit 220 can be configured to access entire memory cells coupled to the one row at a time, alternating different rows. In some embodiments, the control circuit 220 can be configured to alternately assert different first address lines in the plurality of first address lines 250, alternating the plurality of subsets or within a subset. In some embodiments, the control circuit 220 can be configured to assert one entire subset of the plurality of subsets in the plurality of memory cells 203, alternating between the plurality of subsets.

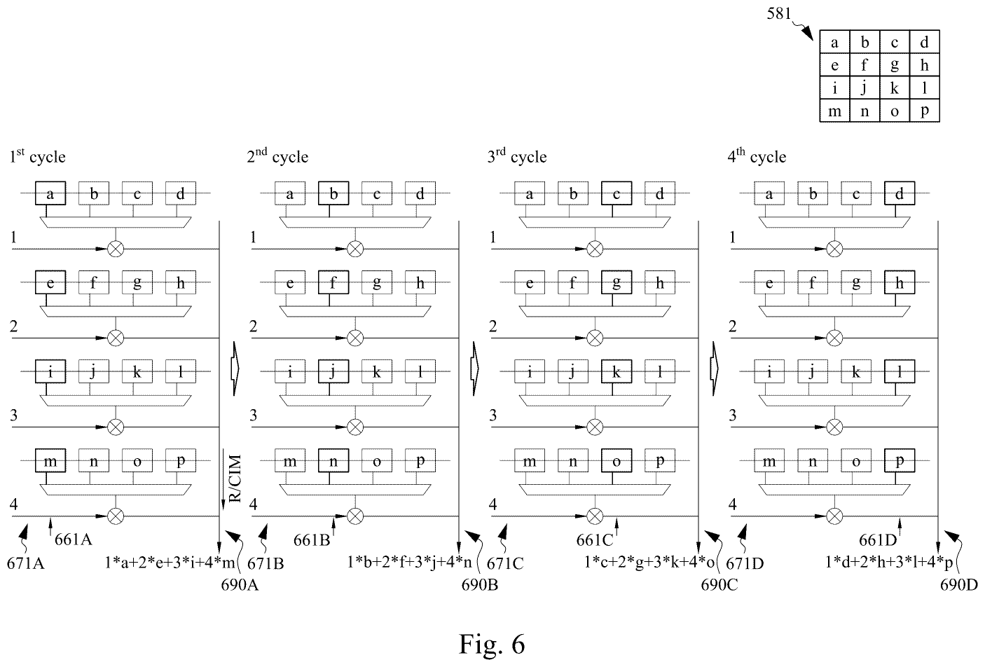

FIG. 6 illustrates a schematic diagram of an example memory circuit, in accordance with some embodiments of the present disclosure. More specifically, shown in FIG. 6 is the memory circuit 202 (the control circuit 220 not shown) at a first time, during an example read operation associated with the weight matrix 581. The read operation shown in FIG. 6 is a non-limiting example. In some embodiments, the memory circuit 202 can be operated with more, fewer, or different operations than shown in or described with respect to FIG. 6.

During the read operation, the control circuit 220 can be configured to access (e.g., read) the plurality of memory cells 203. In some embodiments, the control circuit 220 can be configured to read the plurality of memory cells 203 that have been written based on the weight matrix 581. In some embodiments, the control circuit 220 (and/or the control circuit 120) can be configured to perform MAC operations based on the read operation.

During a first cycle, the control circuit 220 (and/or the control circuit 120) can be configured to provide an input (e.g., input data elements InDE) 671A, while providing a first address signal and a first enable signal 661A. Since the first enable signal 661A asserts a read enable signal on a first column of the plurality of memory cells 203, the first column of the plurality of memory cells 203 (e.g., “a,” “e,” “i,” and “m”) can be read. The control circuit 220 (and/or the control circuit 120) can be configured to perform the MAC operation based on the first column of the plurality of memory cells 203 (e.g., “a,” “e,” “i,” and “m”) and the input 671A. The control circuit 220 (and/or the control circuit 120) can be configured to provide an output (e.g., 1*a+2*e+3*i+4*m) 690A based on the MAC operation.

During a second cycle, the control circuit 220 (and/or the control circuit 120) can be configured to provide an input (e.g., input data elements InDE) 671B, while providing a second address signal and a second enable signal 661B. In some embodiments, the second address signal can be the same as the first address signal provided during the first cycle. Since the second enable signal 661B asserts a read enable signal on a second column of the plurality of memory cells 203, the second column of the plurality of memory cells 203 (e.g., “b,” “f,” “j,” and “n”) can be read. The control circuit 220 (and/or the control circuit 120) can be configured to perform the MAC operation based on the second column of the plurality of memory cells 203 (e.g., “b,” “f,” “j,” and “n”) and the input 671B. The control circuit 220 (and/or the control circuit 120) can be configured to provide an output (e.g., 1*b+2*f+3*j+4*n) 690B based on the MAC operation.

During a third cycle, the control circuit 220 (and/or the control circuit 120) can be configured to provide an input (e.g., input data elements InDE) 671C, while providing a third address signal and a third enable signal 661C. In some embodiments, the third address signal can be the same as the first address signal provided during the first cycle. Since the third enable signal 661C asserts a read enable signal on a third column of the plurality of memory cells 203, the third column of the plurality of memory cells 203 (e.g., “c,” “g,” “k,” and “o”) can be read. The control circuit 220 (and/or the control circuit 120) can be configured to perform the MAC operation based on the third column of the plurality of memory cells 203 (e.g., “c,” “g,” “k,” and “o”) and the input 671C. The control circuit 220 (and/or the control circuit 120) can be configured to provide an output (e.g., 1*c+2*g+3*k+4*o) 690C based on the MAC operation.

During a fourth cycle, the control circuit 220 (and/or the control circuit 120) can be configured to provide an input (e.g., input data elements InDE) 671D, while providing a fourth address signal and a fourth enable signal 661D. In some embodiments, the fourth address signal can be the same as the first address signal provided during the first cycle. Since the fourth enable signal 661D asserts a read enable signal on a fourth column of the plurality of memory cells 203, the fourth column of the plurality of memory cells 203 (e.g., “d,” “h,” “l,” and “p”) can be read. The control circuit 220 (and/or the control circuit 120) can be configured to perform the MAC operation based on the fourth column of the plurality of memory cells 203 (e.g., “d,” “h,” “l,” and “p”) and the input 671D. The control circuit 220 (and/or the control circuit 120) can be configured to provide an output (e.g., 1*d+2*h+3*l+4*p) 690D based on the MAC operation.

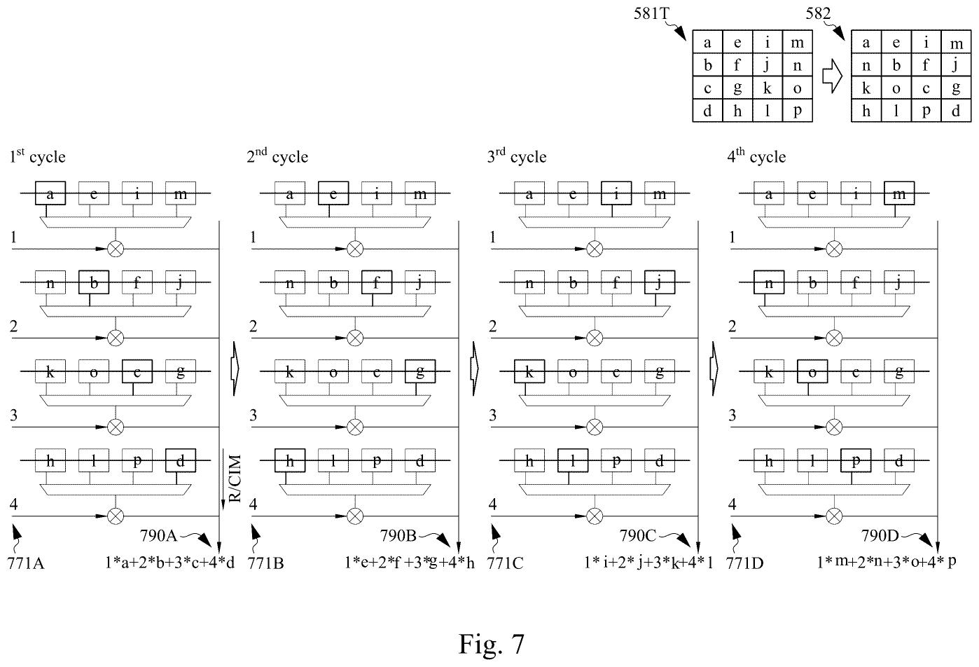

FIG. 7 illustrates a schematic diagram of an example memory circuit, in accordance with some embodiments of the present disclosure. More specifically, shown in FIG. 7 is the memory circuit 202 (the control circuit 220 not shown) at a second time, during an example read operation associated with the weight matrix 581T. The read operation shown in FIG. 7 is a non-limiting example. In some embodiments, the memory circuit 202 can be operated with more, fewer, or different operations than shown in or described with respect to FIG. 7. In some embodiments, the memory circuit 202 can be configured to access the plurality of memory cells 203 based on the shifted matrix 582, in which one or more rows in the weight matrix 581T are shifted.

During the read operation, the control circuit 220 can be configured to access (e.g., read) the plurality of memory cells 203. In some embodiments, the control circuit 220 can be configured to read the plurality of memory cells 203 that have been written based on the weight matrix 581T (or the weight matrix 582). In some embodiments, the control circuit 220 (and/or the control circuit 120) can be configured to perform MAC operations based on the read operation.

During a first cycle, the control circuit 220 (and/or the control circuit 120) can be configured to provide an input (e.g., input data elements InDE) 771A. The control circuit 220 (and/or the control circuit 120) can be configured to provide a first address signal and a first enable signal (e.g., as discussed with respect to FIG. 5). During the first cycle, a first column memory cell (e.g., “a”) in the first row of the plurality of memory cells 203, a second column memory cell (e.g., “b”) in the second row of the plurality of memory cells 203, a third column memory cell (e.g., “c”) in the third row of the plurality of memory cells 203, and a fourth column memory cell (e.g., “a”) in the fourth row of the plurality of memory cells 203 can be read. The control circuit 220 (and/or the control circuit 120) can be configured to perform the MAC operation based on the memory cells (e.g., “a,” “b,” “c,” and “d”), read based on the first address signal and the first enable signal, and the input 771A. The control circuit 220 (and/or the control circuit 120) can be configured to provide an output (e.g., 1*a+2*b+3*c+4*d) 790A based on the MAC operation.

During a second cycle, the control circuit 220 (and/or the control circuit 120) can be configured to provide an input (e.g., input data elements InDE) 771B. The control circuit 220 (and/or the control circuit 120) can be configured to provide a second address signal and a second enable signal (e.g., as discussed with respect to FIG. 5). During the second cycle, a second column memory cell (e.g., “e”) in the first row of the plurality of memory cells 203, a third column memory cell (e.g., “f”) in the second row of the plurality of memory cells 203, a fourth column memory cell (e.g., “g”) in the third row of the plurality of memory cells 203, and a first column memory cell (e.g., “h”) in the fourth row of the plurality of memory cells 203 can be read. The control circuit 220 (and/or the control circuit 120) can be configured to perform the MAC operation based on the memory cells (e.g., “e,” “f,” “g,” and “h”), read based on the second address signal and the second enable signal, and the input 771B. The control circuit 220 (and/or the control circuit 120) can be configured to provide an output (e.g., 1*e+2*f+3*g+4*h) 790B based on the MAC operation.

During a third cycle, the control circuit 220 (and/or the control circuit 120) can be configured to provide an input (e.g., input data elements InDE) 771C. The control circuit 220 (and/or the control circuit 120) can be configured to provide a third address signal and a third enable signal (e.g., as discussed with respect to FIG. 5). During the third cycle, a third column memory cell (e.g., “i”) in the first row of the plurality of memory cells 203, a fourth column memory cell (e.g., “j”) in the second row of the plurality of memory cells 203, a first column memory cell (e.g., “k”) in the third row of the plurality of memory cells 203, and a second column memory cell (e.g., “l”) in the fourth row of the plurality of memory cells 203 can be read. The control circuit 220 (and/or the control circuit 120) can be configured to perform the MAC operation based on the memory cells (e.g., “i,” “j,” “k,” and “l”), read based on the third address signal and the third enable signal, and the input 771C. The control circuit 220 (and/or the control circuit 120) can be configured to provide an output (e.g., 1*i+2*j+3*k+4*l) 790C based on the MAC operation.

During a fourth cycle, the control circuit 220 (and/or the control circuit 120) can be configured to provide an input (e.g., input data elements InDE) 771D. The control circuit 220 (and/or the control circuit 120) can be configured to provide a fourth address signal and a fourth enable signal (e.g., as discussed with respect to FIG. 5). During the fourth cycle, a fourth column memory cell (e.g., “m”) in the first row of the plurality of memory cells 203, a first column memory cell (e.g., “n”) in the second row of the plurality of memory cells 203, a second column memory cell (e.g., “o”) in the third row of the plurality of memory cells 203, and a third column memory cell (e.g., “p”) in the fourth row of the plurality of memory cells 203 can be read. The control circuit 220 (and/or the control circuit 120) can be configured to perform the MAC operation based on the memory cells (e.g., “m,” “n,” “o,” and “p”), read based on the fourth address signal and the fourth enable signal, and the input 771D. The control circuit 220 (and/or the control circuit 120) can be configured to provide an output (e.g., 1*m+2*n+3*o+4*p) 790D based on the MAC operation.

Referring to FIG. 4 to FIG. 7, the control circuit 220 (and/or the control circuit 120) can be configured to perform MAC operations in flexible manners. In some embodiments, the control circuit 220 (and/or the control circuit 120) can be configured to access a first set of memory cells in the plurality of memory cells 203 for a read operation at a first time with a first weight matrix. The control circuit 220 (and/or the control circuit 120) can be configured to access a second set of memory cells in the plurality of memory cells 203 for a write operation at a second time with a second weight matrix that is a transposed (and/or shifted) matrix of the first weight matrix. In some embodiments, the control circuit 220 (and/or the control circuit 120) can be configured to access the first set of memory cells in the plurality of memory cells 203 for a write operation at the first time with the first weight matrix. The control circuit 220 (and/or the control circuit 120) can be configured to access the second set of memory cells in the plurality of memory cells 203 for a read operation at the second time with the second weight matrix that is a transposed (and/or shifted) matrix of the first weight matrix.

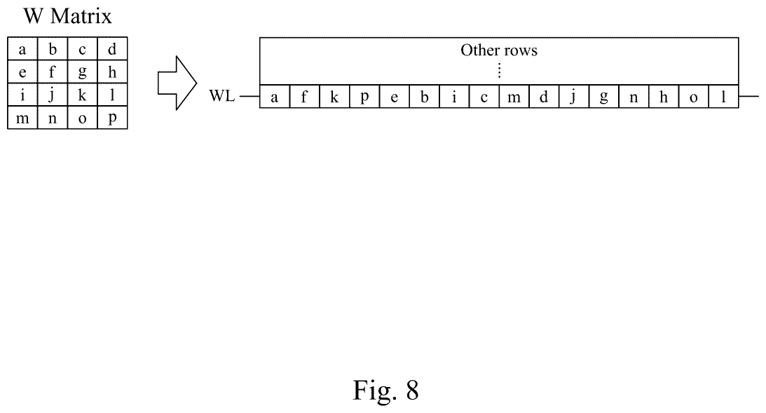

FIG. 8 illustrates schematic diagrams of example weight mapping processes, in accordance with some embodiments of the present disclosure. The weight mapping process shown in FIG. 8 may be associated with the memory circuit 102, the memory circuit 202, etc. Shown in FIG. 8 is a non-limiting example of the weight mapping process. In some embodiments, the control circuit 220 (and/or the control circuit 120) can be configured to reconfigure a weight matrix (e.g., the weight matrix 581, the weight matrix 581T, etc.). For example, when the weight matrix is an n by n matrix, the control circuit 220 (and/or the control circuit 120) can be configured to transform the weight matrix into an 1 by n² matrix. The control circuit 220 (and/or the control circuit 120) can be configured to access memory cells (e.g., the plurality of memory cells 203) and/or perform MAC operations based on the transformed weight matrix (e.g., the 1 by n² matrix).

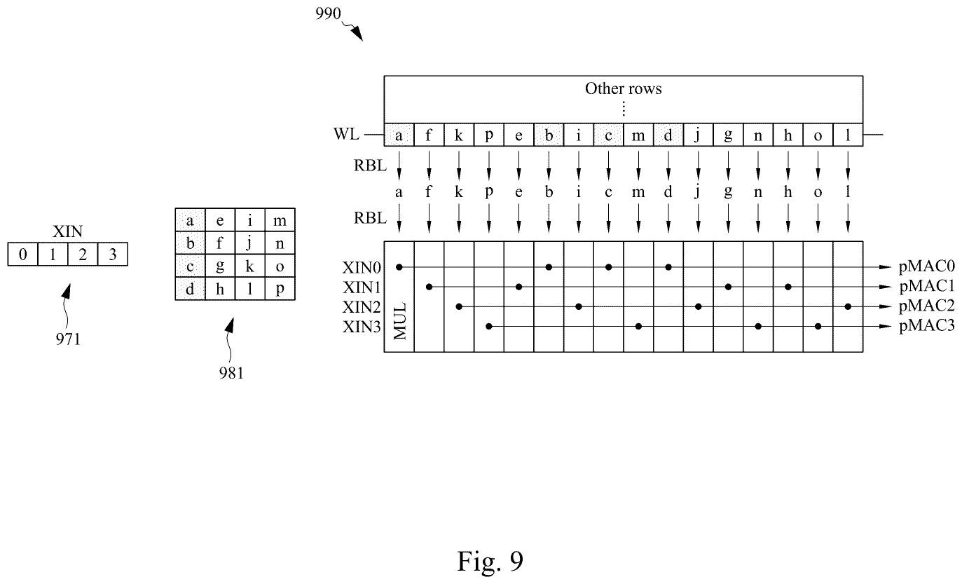

FIG. 9 illustrates schematic diagrams of example weight mapping processes, in accordance with some embodiments of the present disclosure. The weight mapping process shown in FIG. 9 may be associated with the memory circuit 102, the memory circuit 202, etc. Shown in FIG. 9 is a non-limiting example of the weight mapping process. In some embodiments, the control circuit 220 (and/or the control circuit 120) can be configured to reconfigure a weight matrix (e.g., the weight matrix 581, the weight matrix 581T, etc.). For example, when the weight matrix is an n by n matrix, the control circuit 220 (and/or the control circuit 120) can be configured to transform the weight matrix into an 1 by n² matrix. In some embodiments, the control circuit 220 (and/or the control circuit 120) can be configured to perform the transformation for a (non-transposed) weight matrix and a transposed weight matrix.

The control circuit 220 (and/or the control circuit 120) can be configured to transform a (non-transposed) weight matrix 981 into a transformed weight matrix 990. The control circuit 220 (and/or the control circuit 120) can be configured to perform MAC operations based on the transformed weight matrix 990 and an input 971. As shown, based on the MAC operations, the control circuit 220 (and/or the control circuit 120) can be configured to provide an output (pMAC0, pMAC1, pMAC2, pMAC3, etc.). For example, the output pMAC0 can be 0*a+1*b+2*c+3*d. The output pMAC1 can be 0*e+1*f+2*g+3*h. The output pMAC2 can be 0*i+1*j+2*k+3*l. The output pMAC3 can be 0*m+1*n+2*o+3*p.

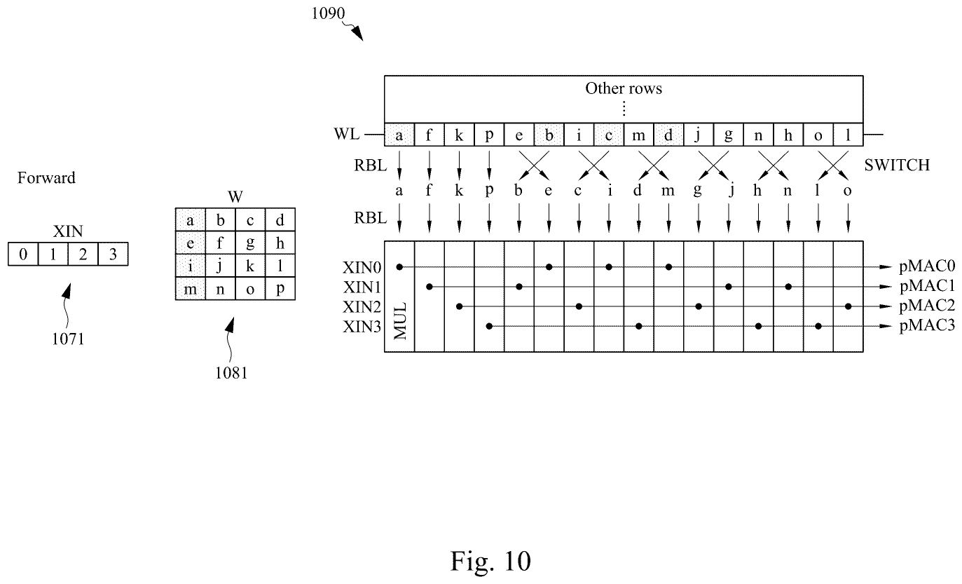

FIG. 10 illustrates schematic diagrams of example weight mapping processes, in accordance with some embodiments of the present disclosure. The weight mapping process shown in FIG. 10 may be associated with the memory circuit 102, the memory circuit 202, etc. Shown in FIG. 10 is a non-limiting example of the weight mapping process. In some embodiments, the control circuit 220 (and/or the control circuit 120) can be configured to reconfigure a weight matrix (e.g., the weight matrix 581, the weight matrix 581T, etc.). For example, when the weight matrix is an n by n matrix, the control circuit 220 (and/or the control circuit 120) can be configured to transform the weight matrix into an 1 by n² matrix. In some embodiments, the control circuit 220 (and/or the control circuit 120) can be configured to perform the transformation for a (non-transposed) weight matrix and a transposed weight matrix.

The control circuit 220 (and/or the control circuit 120) can be configured to transform a transposed weight matrix 1081 into a transformed matrix 1090. The control circuit 220 (and/or the control circuit 120) can be configured to perform MAC operations based on the transformed weight matrix 1090 and an input 1071. In some embodiments, the control circuit 220 (and/or the control circuit 120) can be configured to switch at least one of matrix elements to perform the MAC operations. As shown, based on the MAC operations, the control circuit 220 (and/or the control circuit 120) can be configured to provide an output (pMAC0, pMAC1, pMAC2, pMAC3, etc.). For example, the output pMAC0 can be 0*a+1*e+2*i+3*m. The output pMAC1 can be 0*b+1*f+2*j+3*n. The output pMAC2 can be 0*c+1*g+2*k+3*o. The output pMAC3 can be 0*d+1*h+2*l+3*p.

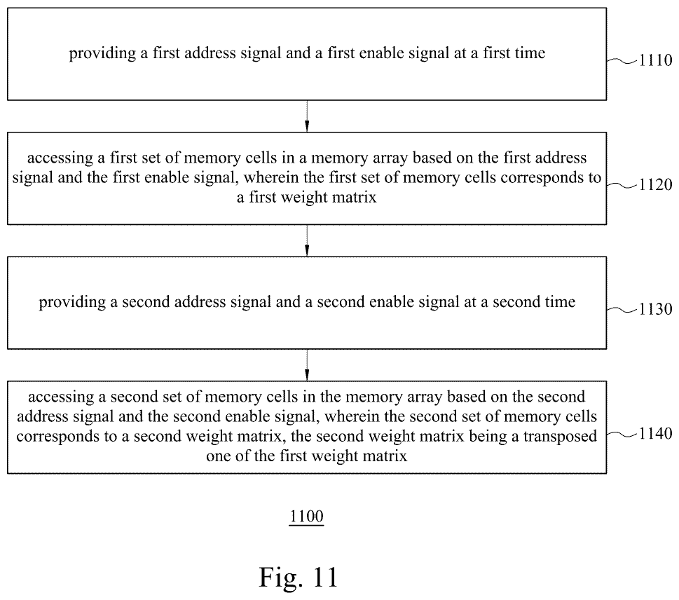

FIG. 11 illustrates a flow chart of an example method 1100 of operating a circuit, in accordance with various embodiments. The example method 1100 can be performed by the control circuit 120, the control circuit 220, etc. or one or more components thereof. As such, the following embodiment of the method 1100 can be described in conjunction with but not limited to at least one of FIG. 1 to FIG. 10. The illustrated embodiment of the method 1100 is provided as an example and does not limit the scope of the present disclosure. Therefore, it shall be understood that any of a variety of the operations of the method 1100 may be omitted, re-sequenced, and/or added while remaining within the scope of the present disclosure.

In a brief overview, the method 1100 can start with operation 1110 of providing a first address signal and a first enable signal at a first time. The method 1100 can continue to operation 1120 of accessing a first set of memory cells in a memory array based on the first address signal and the first enable signal, wherein the first set of memory cells corresponds to a first weight matrix. The method 1100 can continue to operation 1130 of providing a second address signal and a second enable signal at a second time. The method 1100 can continue to operation 1140 of accessing a second set of memory cells in the memory array based on the second address signal and the second enable signal, wherein the second set of memory cells corresponds to a second weight matrix, the second weight matrix being a transposed one of the first weight matrix.

At operation 1110, a control circuit (e.g., the control circuit 120, the control circuit 220) can provide a first address signal (e.g., address signals 451A, 451B, 451C, 451D, address signals described with respect to FIG. 6 etc.) and a first enable signal (e.g., enable signals 461A, 461B, 461C, 461D, 661A, 661B, 661C, 661D, etc.) at a first time.

At operation 1120, the control circuit can access a first set of memory cells in a memory array (e.g., the plurality of memory cells 203) based on the first address signal and the first enable signal. The first set of memory cells can correspond to a first weight matrix (e.g., the weight matrix 581). In some embodiments, the control circuit can be configured to access the memory cells based on a logic AND operation of the first address signal and the first enable signal.

At operation 1130, the control circuit can provide a second address signal (e.g., address signals 551A, 551B, 551C, 551D, address signals described with respect to FIG. 7, etc.) and a second enable signal (e.g., enable signals 561A, 561B, 561C, 561D, enable signals described with respect to FIG. 7, etc.) at a second time. In some embodiments, the control circuit can be configured to access the memory cells based on a logic AND operation of the first address signal and the first enable signal.

At operation 1140, the control circuit can access a second set of memory cells in the memory array based on the second address signal and the second enable signal. The second set of memory cells can correspond to a second weight matrix (e.g., the weight matrix 581T). The second weight matrix can be a transposed one of the first weight matrix.

As used herein, the terms “about” and “approximately” generally indicates the value of a given quantity that can vary based on a particular technology node associated with the subject semiconductor device. Based on the particular technology node, the term “about” can indicate a value of a given quantity that varies within, for example, 10-30% of the value (e.g., +10%, ±20%, or ±30% of the value).

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A circuit for weight mapping for a computation in memory (CIM) circuit, comprising:
a plurality of memory cells;
a plurality of first address lines, each of which is coupled with a corresponding one of the plurality of memory cells; and
a plurality of second address lines, each of which is coupled with a set of cells in the plurality of memory cells,
wherein one or more cells in the plurality of memory cells are configured to be accessed for one or more weight values, when one or more of the plurality of first address lines and one or more of the plurality of second address lines corresponding to the one or more cells in the plurality of memory cells are asserted, and
wherein the one or more cells that are accessed at a first time correspond to a first weight matrix, and the one or more cells that are accessed at a second time correspond to a second weight matrix, the second weight matrix being a transposed one of the first weight matrix.

2. The circuit of claim 1, further comprising a plurality of logic AND gates, each of which is operably coupled between a corresponding one of the plurality of first address lines and a corresponding one of the plurality of second address lines.

3. The circuit of claim 2, wherein each of the plurality of logic AND gates includes a first input to receive an enable signal and a second input to receive an address signal.

4. The circuit of claim 2, wherein each of the plurality of logic AND gates includes an output operably coupled with the corresponding one of the plurality of memory cells.

5. The circuit of claim 1, wherein the first weight matrix is an n by n matrix, and the plurality of memory cells are accessed based on an 1 by n² matrix.

6. The circuit of claim 1, wherein the one or more cells in the plurality of memory cells are configured to be accessed for a read operation at the first time with the first weight matrix, and the one or more cells in the plurality of memory cells are configured to be accessed for a write operation with the second weight matrix at the second time.

7. The circuit of claim 1, wherein the plurality of first address lines include a plurality of subsets, each of which is coupled with a corresponding row of the plurality of memory cells, and wherein different first address lines are asserted alternately, alternating the plurality of subsets.

8. The circuit of claim 1, wherein the plurality of first address lines include a plurality of subsets, each of which is coupled with a corresponding row of the plurality of memory cells, and wherein one entire subset of the plurality of subsets is asserted, alternating between the plurality of subsets.

9. The circuit of claim 1, wherein a first number of address lines in the plurality of first address lines corresponds to a number of memory cells in the plurality of memory cells, and a second number of address lines in the plurality of second address lines corresponds to a number of rows or columns in the plurality of memory cells.

10. A circuit for weight mapping for a computation in memory (CIM) circuit, comprising:
a memory array; and
a control circuit operably coupled with the memory array, the control circuit configured to:
provide an enable signal and an address signal; and
access, based on the enable signal and the address signal, at least one memory cell of the memory array,
wherein the control circuit is configured to provide a first address signal at a first time to access the memory array based on a first weight matrix, and configured to provide a second address signal at a second time to access the memory array based on a second weight matrix, the second weight matrix being a transposed one of the first weight matrix.

11. The circuit of claim 10, further comprising a multiplexer operably coupled between the memory array and the control circuit.

12. The circuit of claim 11, wherein the multiplexer includes at least one logic gate and a plurality of address lines.

13. The circuit of claim 12, wherein the at least one logic gate includes a logic AND gate including a first input to receive the enable signal and a second input to receive the address signal.

14. The circuit of claim 12, wherein the at least one logic gate includes a logic AND gate including an output operably coupled with a corresponding memory cell of the memory array.

15. The circuit of claim 10, wherein the first matrix is an n by n matrix, and the control circuit is configured to access the memory array based on an 1 by n² matrix.

16. The circuit of claim 10, wherein the control circuit is configured to write the memory array based on the first weight matrix, and configured to read the memory array based on the second weight matrix.

17. The circuit of claim 10, wherein the control circuit is configured to alternately assert different rows of the memory array.

18. The circuit of claim 17, wherein when the control circuit asserts one row of the memory array, the control circuit is configured to access entire memory cells coupled to the one row of the memory array at a time.

19. A method for weight mapping for a computation in memory (CIM) circuit, comprising:
providing a first address signal and a first enable signal at a first time;
accessing a first set of memory cells in a memory array based on the first address signal and the first enable signal, wherein the first set of memory cells corresponds to a first weight matrix;
providing a second address signal and a second enable signal at a second time; and
accessing a second set of memory cells in the memory array based on the second address signal and the second enable signal, wherein the second set of memory cells corresponds to a second weight matrix, the second weight matrix being a transposed one of the first weight matrix.

20. The method of claim 19, further comprising:
accessing the first set of memory cells based on a logic AND operation of the first address signal and the first enable signal.
